(19) United States
(12) Patent Application Publication
(10) Pub. No.: US 2025/0298069 A1
(43) Pub. Date: Sep. 25, 2025

(54) DEVICE AND METHOD FOR CHARACTERIZING THE CURRENT COLLAPSE OF GAN TRANSISTORS

(71) Applicant: COMMISSARIAT A L'ENERGIE ATOMIQUE ET AUX ENERGIES ALTERNATIVES, Paris (FR)

(72) Inventors: Van-Sang NGUYEN, Grenoble Cedex 09 (FR); Anthony BIER, Grenoble Cedex 09 (FR); Stéphane CATELLANI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/862,418

(22) PCT Filed: May 2, 2022
(86) PCT No.: PCT/FR2022/050841

§ 371 Date: Nov. 1, 2024

(51) Int. Cl. G01R 31/26; G01R 1/20; G01R 27/08

(52) U.S. Cl. CPC G01R 31/2621; G01R 1/206; G01R 27/08

(57) ABSTRACT

A device for evaluating a dynamic resistance in a conducting state of a GaN-based transistor. The device including a test circuit provided with a circuit, the GaN-based transistor, forming an arm of the circuit, the device being provided with a stage for controlling the switch elements of the circuit to alternately set the switch elements of the circuit in a first configuration and then in a second configuration, the control stage being configured to trigger a connection of a drain-source voltage measuring stage to the GaN-based transistor after the circuit is set in the first configuration, and to trigger a disconnection of the drain-source voltage measuring stage from the GaN-based transistor before the circuit is set in the second configuration.

### TECHNICAL FIELD

The present application relates to the field of GaN-based transistors and relates in particular to an improved measuring device allowing evaluating the dynamic resistance in the conducting state of such transistors.

### PRIOR ART

GaN-based transistors have the particular advantage of withstanding high current densities as well as very high chopping frequencies. They find applications in the field of power circuits such as power converters and inverters.

However, these transistors are subject to a current collapse phenomenon (“current collapse” according to the Anglo-Saxon terminology) due to electron traps in their semiconductor structure. Such a phenomenon is mentioned for example in the document by T. Hasan, “Mechanism and Suppression of Current Collapse in AlGaN/GaN High Electron Mobility Transistors”, PHD thesis-University of Fukui, Japan, 2013.

The origin of such traps could be the result of several factors, like for example crystalline defects, dislocations, or the presence of impurities. Such traps could also be found in the interface between different semiconductor materials and passivation layers. In GaN-based transistors, the traps are located mainly in the GaN or in the interface between this layer and another layer of a large Gap material, for example AlGaN-based.

The current collapse phenomenon significantly affects circuits in particular power circuits such as converters or inverters, which is all the more when an operation at high temperature and at low voltage is required. This might even result in a thermal breakage of the components.

The document: “The effect of dynamic On-state resistance to systems losses in GaN-based hard switching applications”, by R. Hou, J. Lu, PCIM 2019, and the document: “The impact of GaN HEMT dynamic On-state resistance on converter performance”, by Cai et al., IEEE Applied Power Electronics Conference and Exposition, Tampa, FL, March 2017, disclose different methods for evaluating the drain-source dynamic resistance of a GaN transistor.

This poses the problem of finding a device allowing carrying out a measurement of the drain-source dynamic resistance of a GaN transistor having an improved accuracy and which is easily adaptable to serial testing of such components.

### DESCRIPTION OF THE INVENTION

According to one embodiment, the present invention relates to a device for evaluating the dynamic resistance in the conducting state of a GaN-based transistor, comprising a test circuit having:
a first circuit arm, said first arm being provided with a first switch element and with a second switch element connected together at a first node, said test circuit being provided with a third switch element connected to the second node, said third switch element being able to form a second arm of said test circuit with said GaN-based transistor when said GaN-based transistor is connected to the second node,
a power supply delivering a supply voltage to the first arm and to the second arm,
a branch between the first node and the second node provided with an inductive load and with a current sensor, to measure a current flowing through this inductive load,
a measuring switch for alternately connect said GaN-based transistor to a drain-source voltage measuring stage in the conducting state of said GaN-based transistor, and disconnect said GaN-based transistor from said drain-source voltage measuring stage when said measuring switch is set in the non-conducting state,
a control stage of said first, second and third switch elements, of said GaN-based transistor and of the measuring switch, the control stage being configured to:
according to a so-called “measurement” phase, alternately set, once or several times, the test circuit in a first configuration, then in a second configuration, the first configuration being a configuration in which the first switch element and said GaN-based transistor are made conducting whereas the second switch element and the third switch element are made non-conducting, so as to set said power supply in series, said branch, and said GaN-based transistor, the second configuration being a configuration during which the second switch element and the third switch element are in the conducting state whereas the first switch element and said GaN-based transistor are set in the non-conducting state so as to set said branch in closed circuit with said power supply,
the control stage being configured to trigger a connection of the drain-source voltage measuring stage to said GaN-based transistor after the test circuit is set in the first configuration, and to trigger a disconnection of the drain-source voltage measuring stage of said GaN-based transistor before the test circuit is set in the second configuration.

In comparison with pulse-type test devices, the test circuit of the device according to the invention enables a characterization that is closer to the behavior of GaN transistors in their application field.

According to an advantageous embodiment, the control stage is further configured, prior to the measurement phase, to implement a soaking phase lasting an adjustable predetermined duration, by making the first switch and the third switch conducting whereas the second switch and the GaN-based transistor are kept non-conducting so as to set the first node and the second node at said supply voltage.

According to a possible implementation, the control stage is configured to trigger a connection of the drain-source voltage measuring stage to said GaN-based transistor a first predetermined adjustable delay after the test circuit is set in the first configuration, and to trigger a disconnection of the drain-source voltage measuring stage from said GaN-based transistor, a second predetermined adjustable delay before the test circuit is set in the second configuration.

According to a possible embodiment, the drain-source voltage measuring stage comprises an operational amplifier mounted as a follower and whose non-inverting input could be connected to the drain electrode of the GaN-based transistor.

Advantageously, the control stage is configured to trigger a switch from the first configuration into the second configuration or from the second configuration into the first configuration according to the variation of a signal originating from a circuit for regulating the current of said inductive load, this signal itself resulting from a comparison between said current flowing through the inductive load and a setpoint value.

According to a possible implementation, the regulation circuit is configured to establish the difference between an averaged value of the current flowing through the inductive load and said setpoint, and includes a corrector stage, in particular of the proportional integral type, configured to calculate a duty cycle from this difference, this duty cycle, comprised between zero and one, being representative of a proportion between the duration of said first configuration and the total duration of the successive first configuration and second configuration, the value of the duty cycle being transmitted via said signal originating from a regulation circuit to a pulse-width modulation circuit of the control stage to control the gate of the first switch element, of the second switch element, of the third switch element, and of said GaN-based transistor.

According to a possible implementation, the device may further comprise a means for heating the GaN-based transistor. In particular, this heating means may be provided with an infrared radiation source configured to emit a localized infrared light beam on the GaN-based transistor.

The GaN-based transistor is typically brought to be temporarily connected on the test circuit.

Thus, according to one possibility, said circuit is arranged on a support provided with connection areas or structures on which a source electrode, a drain electrode and a gate electrode of the GaN transistor can respectively be connected in a removable manner.

Advantageously, the GaN-based transistor is embedded and/or mounted on a package and said test circuit is arranged on a support, the connection structures consisting of connection and receiving structures respectively intended to enable a secure assembly of the transistor on said support.

According to another possibility, the transistor is arranged on a wafer (“wafer” according to the Anglo-Saxon terminology) including a plurality of electronic chips, each electronic chip being provided with at least one GaN transistor, the GaN transistor being connected to said support of the test circuit.

According to another aspect, the present application relates to a microelectronic method comprising at least one step of evaluating the dynamic resistance in the conducting state of a GaN transistor using a device as defined before, the method comprising steps of:
connecting the GaN-based transistor to connection areas in order to assess its drain-source dynamic resistance in the conducting state, then
disconnecting the transistor from said connection areas, then,
cutting the support in order to separate said electronic chips.

### BRIEF DESCRIPTION OF THE DRAWINGS

The present invention will be better understood in light of the following description and from the appended drawings wherein:

FIG. 1 is intended to illustrate an example of a structure of a GaN-based transistor whose drain-source dynamic resistance in the conducting state can be assessed by means of a device implemented according to the invention.

FIG. 2 is intended to illustrate a device for evaluating the drain-source dynamic resistance in the conducting state of a GaN-based transistor wherein the transistor is arranged as a switch element of a test circuit with several switches and the arrangement of which is similar to that of an inverter-type setup.

FIG. 3 gives an example of an operation time chart of the device of FIG. 2.

FIG. 4 is intended to illustrate an example of an infrared beam heating device for heating in a localized manner the GaN transistor when a measurement of the dynamic resistance in the conducting state of the latter is performed.

FIG. 5A is intended to illustrate an example of an arrangement of the connection areas in the test circuit and to which the GaN-based transistor could be temporarily and removably connected while an assessment of the dynamic resistance in the conducting state of this transistor is being carried out.

FIG. 5B is intended to illustrate an example of an arrangement of the connection and receiving structures of the test structure to which the GaN-based transistor could be temporarily and removably connected while an assessment of the dynamic resistance in the conducting state of this transistor is being carried out.

FIG. 6 is intended to illustrate a measurement performed when the GaN-based transistor is still arranged on the wafer (wafer) on which it has just been manufactured.

Identical, similar or equivalent portions of the different figures bear the same reference numerals so as to facilitate passage from one figure to another.

The different portions shown on the figures are not necessarily plotted according to a uniform scale, to make the figures more legible.

### DETAILED DESCRIPTION OF PARTICULAR EMBODIMENTS

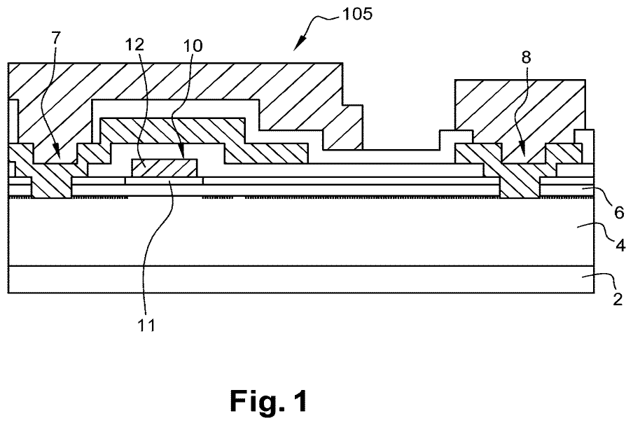

FIG. 1 now depicts a schematic sectional view of an example of a structure of a GaN-based transistor 105 whose drain-source dynamic resistance in the conducting state R_{DS_ON_dyn} is assessed.

The transistor 105 is made from a semiconductor substrate 2, for example silicon-based, on which a semiconductor block comprising a heterojunction is arranged. The heterojunction is made in a stack comprising a first layer 4 of a III-N semiconductor material having a first band gap and a second layer 6 of a III-N semiconductor material having a second band gap, larger than said first band gap. For a so-called “GaN” or “GaN-based” transistor, the first layer 4 is typically GaN-based, whereas the second layer 6 may, for example, be made of AlGaN.

The transistor further comprises source 7 and drain 8 electrical contacts, which are arranged on and in contact with regions of the second layer 6. Each of the electrical contacts 7 and 8 may be a metallic layer or a stack of metallic layers. A two-dimensional electron gas 2-DEG may be formed in a channel region located in the first layer 4, typically under the interface between the second layer 6 and the first layer 4.

The transistor further comprises a gate electrode 10 which may be arranged in contact with, and herein over a portion of, the second layer 6 to control the two-dimensional electron gas. The gate electrode 10 is formed by an upper region 12 which is metal-based and which is in contact with a semiconductor lower region 11, for example p-GaN based.

In order to be able to prevent the current collapse phenomenon (“current collapse”), the value of the dynamic resistance of such a GaN transistor 105 should be assessed. Advantageously, such an assessment may be performed directly on the wafer (“wafer” according to the Anglo-Saxon terminology), in other words even before this transistor is separated from other transistors with which it is formed collectively on this same wafer and before this wafer is divided.

Alternatively, it is possible to assess this dynamic resistance value after division steps (“dicing” or “wafer dicing” according to the Anglo-Saxon terminology) and optionally after the transistor is packaged according to a packaging step (“packaging” according to the Anglo-Saxon terminology).

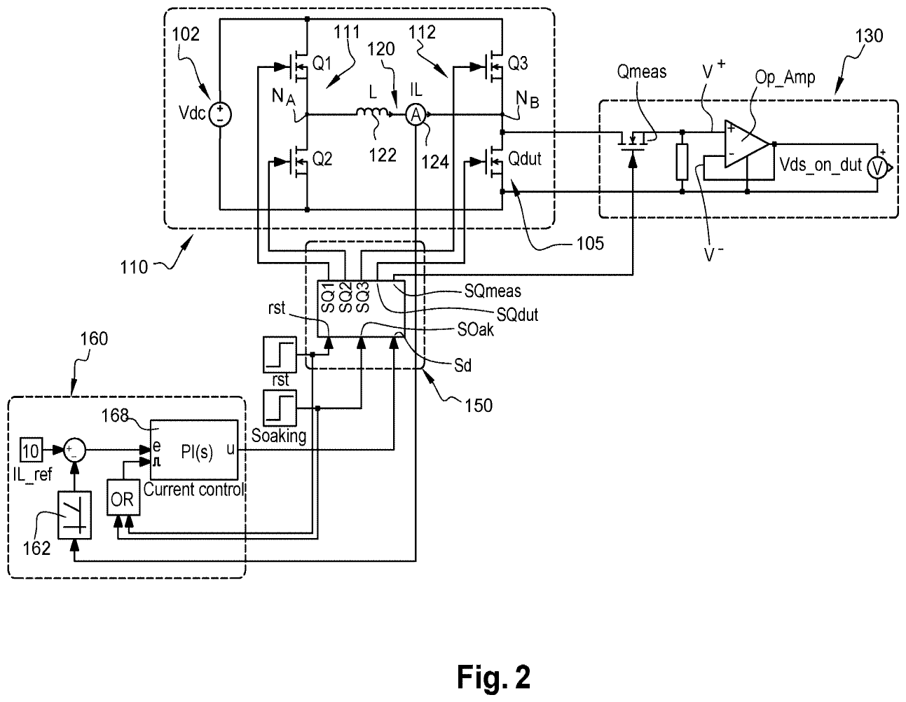

To allow measuring the drain-source dynamic resistance of a transistor of the same type as that one described before in connection with FIG. 1, it is provided to integrated it into a circuit 110, as illustrated in FIG. 2, so as to form a test circuit with switches the arrangement of which is similar to that of a bridge inverter.

The circuit 110 is powered by a DC power supply 102-DC/-DC for example in the range of 10 volts up to 3 kV, in particular between 100 volts and 1,700V.

The circuit 110 is provided with a first arm 111 comprising a first switch element Q1, in this example a first transistor, and a second switch element Q2, herein a second transistor, the second switch element being connected to the first switch element at a first node NA.

The circuit 110 is also provided with a second arm 112 comprising a third switch element Q3, herein a third transistor. The GaN transistor 105 whose drain dynamic resistance R_{DS_ON_dyn} is to be assessed is intended to complete the second arm and form the fourth switch element of the test circuit. The third transistor Q3 and the GaN transistor 105 are herein connected at a second node NB.

Advantageously, the GaN transistor 105 is temporarily set in connection with the other switch elements Q1, Q2, Q3 to form the circuit 110. In this case, once the measurement(s) of the drain-source dynamic resistance in the conducting state R_{DS_ON_dyn} have been performed, it is possible to replace the transistor 105 with another transistor of the same type whose drain-source dynamic resistance in the conducting state R_{DS_ON_dyn} is to be assessed.

The transistors, herein forming respectively the first, second and third switch element Q1, Q2, Q3, are typically made in a technology distinct from that one of the GaN transistor 105. Thus, these transistors may, in particular, consist of MOS transistors, advantageously power MOSs whose channel region is for example formed in a silicon layer. In the illustrated particular embodiment, NMOS enhancement transistors are used.

It is provided to measure a current IL in a circuit branch 120 between the first node N_{A} and this second node N_{B} in order to obtain an image of the drain-source current IDS_ON of the GaN transistor 105 when the latter is conducting.

To assess the current I_{L}, a circuit branch 120 between the first node N_{A} and the second node NB comprises a current sensor 124. A “hall effect” type sensor, like for example a sensor commercialized by the company LEM, in particular the type LEM CKSR, 50A could allow measuring the current flowing through an inductive load 122 with an inductance L. Preferably, this inductive load 122 is provided with a very low high-frequency parallel parasitic capacitance for example in the range of 0.3 pF within a frequency range between 10 MHz and 60 MHz. The current IL is the image of the current flowing through the GaN transistor 105 when the latter is set in the conducting state and the branch 120 is set in series with this transistor 105.

A stage 130 for measuring the drain-source voltage of the GaN transistor 105 when the latter is set in the conducting state is also provided for and coupled with the drain electrode D and with the source electrode S of the GaN transistor 105.

The stage 130 for measuring the drain-source voltage, is herein provided with an operational amplifier Op-Amp according to a follower setup, with an output looping back on its inverting input.

The operational amplifier Op-Amp outputs a voltage Vds_ON_dut proportional to a difference of potentials between a potential of a drain electrode D of the transistor 105 set in the conducting state and a potential of a source electrode S of the first transistor 105 set in the conducting state.

In the illustrated example, the drain D of the transistor 105 can be coupled during a measurement phase at the non-inverting input V+ of the operational amplifier Op-Amp.

A so-called “measuring” switch Qₘₑₐₛ is arranged between the drain electrode D of the transistor 101 and the non-inverting input V+ of the operational amplifier Op-Amp. In this example, this measuring switch Qₘₑₐₛ is formed by a coupling transistor, herein of the N type, in particular an enhancement NMOS, which gate is controlled by a measurement control signal SQmeas, to activate the coupling transistor M₁ and trigger a measurement phase.

When the switch Qₘₑₐₛ is set in the conducting state, the drain electrode D of the transistor 105 is subsequently connected to the amplifier.

The measurement of the drain-source voltage is herein performed when setting the GaN transistor 105 in the conducting mode. Once the measurement phase is completed, the measurement control signal SQmeas is modified so as to disconnect the drain electrode D of the transistor 105 from the amplifier Op-Amp.

Advantageously, the operational amplifier Op-Amp is provided for with a high slew rate (“Slew Rate” according to the Anglo-Saxon terminology), i.e. typically of at least several hundred volts per μs, for example in the range of 400 V/μs. Advantageously, the operational amplifier Op-Amp may be powered between V+ and V− by an external battery, which allows minimizing disturbances in the measurements.

The switch elements Q1, Q2, Q3 and the transistor 105 whose drain-source dynamic resistance RDS_ONdyn should be measured, and in particular their respective active and inactive (i.e. respectively conducting or non-conducting) states are respectively controlled by control signals SQ1, SQ2, SQ3, SQ_{DUT}.

A control stage 150 connected to the test circuit 110 may be provided to produce these control signals SQ1, SQ2, SQ3, SQ_{DUT}, respectively of the switch elements Q1, Q2, Q3 and of the transistor 105, herein applied on their respective gate electrodes, as well as the measurement control signal SQmeas. These signals are typically produced in the form of pulses and according to sequences corresponding to the different phases of operation of the device, in particular to implement a so-called “soaking” phase and a so-called current regulation and measurement” phase also so-called “measurement phase”. The control stage 150 is typically a digital circuit or provided with a digital block or is integrated into a digital circuit, for example of the microcontroller type or a programmable logic circuit.

In the illustrated example of operation, the control stage 150 itself receives signals Srst, Ssoak and Sd.

The signal Srst is a reset signal of the control stage 150 to reset it in a so-called “stop” phase. The respective control signals SQ1, SQ2, SQ3, SQ_{DUT}, SQmeas are set during this stop phase in an inactive state, herein a low state, so that the switches Q1, Q2, Q3, Q_{DUT}, Qₘₑₐₛ are deactivated (i.e. in the non-conducting state).

The signal Ssoak is a signal triggering the end of the so-called “soaking” phase, which takes place prior to the measurement phase, and whose duration could be adjusted and modulated from one measurement of the dynamic resistance to another.

In particular, the duration of soaking may depend on the intended application of the transistor being tested. It is also possible to carry out different tests with distinct soaking durations from one test to another in order to determine the characteristics of the transistor. For example, a “dSpace”-type servo-controller produced by the company dSpace GmbH or an FPGA-type programmable logic circuit may be used to modulate this duration.

The signal Sd may be an indicator of a duty cycle. The control stage 150 could modify the respective states of some of its control signals SQ1, SQ2, SQ3, SQ_{DUT}, SQmeas subsequently to the reception of such a signal.

This signal Sd itself may be produced by a regulation stage 160. Such a stage 160 receives a measurement of the current I_{L} measured by the current sensor 124, may recover an average value of this current via a block 162, which produces a measured current average in order to be able to compare this average value with a reference current value IL_ref serving as a setpoint value. The result of this comparison is transmitted to a corrector stage 168, herein of the PI (“proportional-integral”) type which produces the signal Sd. The regulation may be reset by reception of the reset signal Srst of the control stage 150 or of the signal Ssoak triggering the end of the soaking phase.

The control stage 150 may be configured to trigger a switch from the first configuration into the second configuration according to the following method:
The current measured in the inductance IL may be averaged and compared with a predetermined current setpoint IL_ref, the result of this comparison is used by the regulation stage 160 provided with a corrector stage 168, in particular a PI-type corrector, configured to calculate a duty cycle based on this current difference.
This duty cycle, comprised between zero and one, is representative of a proportion between the duration of the first configuration and the total duration of the two successive configurations, this total duration being preferably fixed and predetermined.
The value of the calculated duty cycle is transmitted in the form of a signal Sd and used by a “pulse-width modulation” (MLI) type circuit belonging to the control stage 150 and which controls the four transistors Q1, Q2, Q3, 105 successively according to the first configuration and then the second configuration and again according to the first configuration followed by the second configuration and so on until stoppage of the test. Such a stoppage may be triggered when a convergence criterion is met or a predetermined measurement duration is elapsed.

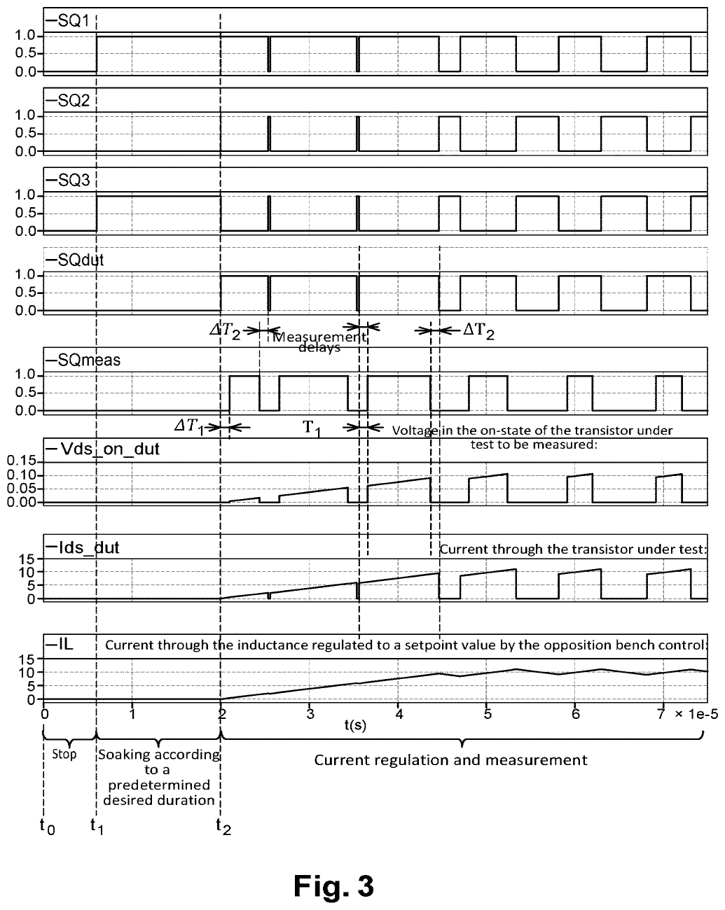

An example of operation of the test device with the different aforementioned phases of operation is illustrated in the time chart of FIG. 3, giving a possible assessment of the respective control signals SQ1, SQ2, SQ3 of the switch elements Q1, Q2, Q3, of the control signal SQ_{DUT} of the transistor 105 being tested, of the measurement phase triggering signal SQmeas, of the voltage VDS_on_DUT of the GaN-based transistor 105, of the current I_{DS_DUT} of the GaN-based transistor 105, and of the current I_{L} flowing through the inductive load 122 and flowing in the branch 120.

Prior to the so-called “soaking” operation phase (between a time point t₀ and a time point t₁), the device is in the stop phase and the signals SQ1, SQ2, SQ3, SQ_{DUT}, SQmeas are herein in a low state corresponding to a deactivated or non-conducting state of the transistors they respectively control.

Then, prior to a measurement phase, the soaking phase lasting a determined and adjustable duration is implemented.

For example, it is possible to provide for the duration of this phase lasting between one microsecond and several seconds and being set at a predetermined duration. This predetermined duration may be selected among different durations for example 1 μs, 2 μs, 2 s and 10 s depending on the characteristics of the transistor 105 being tested. The soaking duration may be adjusted from one measurement to another preformed on the same transistor 105 or on a next transistor replacing the transistor 105 in the second arm of the test circuit 110.

During this soaking phase, herein triggered at a time point t₁, the control signals SQ₁ and SQ₃ of the first switch element Q1 and of the third switch element Q3 are set in a first state, herein a high state, so as to make the first switch Q1 and the third switch Q3 conducting, whereas the second switch Q2 and the GaN-based transistor 105 are kept non-conducting via the control signals SQ₁ and SQdut kept in a second state, herein a low or deactivated state. Thus, said GaN-based transistor 105 is coupled to the power supply 102 whereas the nodes N_{A} and N_{B} are set at the same potential and in particular at the supply voltage. Thus, during this soaking phase, the supply voltage between the drain and the source of the transistor 105 is imposed.

Advantageously, the soaking and its duration are herein controlled without having to add additional arms to the test circuit 110 and without complicating the layout of this test circuit.

The soaking phase ends at a time point t₂ to start afterwards the current regulation and measurement phases.

The control signal SQ_{DUT} of the transistor 105 being tested is then modified by the control stage 150 and in particular set in a state, herein a high state, so as to make the GaN transistor 105 conducting, in other words activate it. In turn, the signals SQ2, SQ3 of the second switch element Q2 and of the third switch element Q3 are kept in a low state so as to keep the second switch Q2 and the third switch element Q3 deactivated (i.e. non-conducting), whereas the signal SQ₁ is kept in a high state so as to keep the first switch element Q1 activated (i.e. conducting). The power supply 102, the branch 120 and the transistor 105 are then set in series. Thus, the test circuit 110 is in a first configuration corresponding to a first set of states of the switch elements Q1, Q2, Q3 and of the transistor 105.

To perform a measurement, the control signal SQmeas is modified and activated with an adjustable delay ΔT1 after the time point t₂ of start-up of the first configuration in order not to disturb the switching behavior of the transistor 105. Thus, the transistor Qₘₑₐₛ of the measuring stage 130 may be armed or made conducting a delay ΔT1, for example ten nanoseconds, after the GaN transistor 105 is armed. The measuring stage 130 and in particular the amplifier Op-Amp is then connected to the terminals of the GaN transistor 105.

Then, once the measurement of the drain-source voltage Vds_on_dut of the transistor 105 is performed, the measuring stage 130 and in particular the amplifier Op-Amp is disconnected from the GaN transistor 105, by deactivating (i.e. blocking) the measuring switch Qₘₑₐₛ. Afterwards, the transistor 105 is disarmed (i.e. made non-conducting) a predetermined delay ΔT2 after deactivation of the switch Qₘₑₐₛ. The signals SQ1, SQ2, SQ3, respectively of the first switch element Q1, of the second switch element Q2 and of the third switch element Q3 are modified at the same time and respectively set in states so as to deactivate (i.e. block) the first switch Q1, and activate (i.e. make conducting) the second switch element Q2 and the third switch element Q3.

Thus, one could switch from the first configuration into a second configuration corresponding to a second set of states of the switch elements Q1, Q2, Q3 and of the transistor 105. In this second configuration, the power supply 102 and the branch 120 form a closed circuit.

The respective durations of the first configuration and of the second configuration depend on that one during which the measurement triggering signal SQmeas is activated, itself deduced from the signal SQdut, itself formed from the signal Sd supplied by the regulation stage. The signal SQmeas replicates the variations of the signal SQdut within the delay margins ΔT1 and ΔT2.

The switch Qₘₑₐₛ is armed by the signal SQmeas (in other words, it is set in the ON or conducting state) at a later time after the transistor 105 being tested whose state is controlled by the signal SQdut and the switch Qₘₑₐₛ is closed (in other words, it is set in the OFF state) at an earlier time before the transistor 105 to avoid a measurement disturbance related to switching of the transistor 105.

Thus, during this measurement phase, the control signals SQ1, SQ2, SQ3, SQ_{DUT} alternate at least once and typically several times, between a first set of states and a second set of states, so that the test circuit 110 alternates several times between the first configuration and the second configuration.

Thus, the switch elements Q1, Q2, Q3 and 105 could be controlled according to an opposition method like that one described for example in the document “Use of Opposition method in the test of high-power electronic converters”, by Forest et al., IEEE transaction on industrial electronics, 2006.

The total duration of the measurement phase may be adjusted according to a predetermined test duration or correspond to a predetermined number of switchings between the first configuration and the second configuration.

The end of the measurement phase may also be established when a convergence criterion is met. For example, such a convergence criterion may be such that, when upon completion of several measurement samples of R_{DS_ONdyn}, the measured value of the measured resistance R_{DS_ONdyn} no longer varies by K %, for example with K=5, the end of the measurement phase is triggered.

The end of the measurement phase may also be triggered by a user of the test device, for example when he/she sees on a measuring instrument, such as an oscilloscope, that a convergence of the inductance current IL around the setpoint value is reached.

The characterization of the GaN-based transistor 105 and in particular the measurements of I_{LOAD} of V_{drop_DS_ON} in order to assess the resistance R_{DS_ON_dyn} are typically carried out typically by heating the transistor 105 at a temperature which may be comprised for example between 25° C. and 175° C., to the extent that the operating temperature of the assessed transistor 105 is typically within this range.

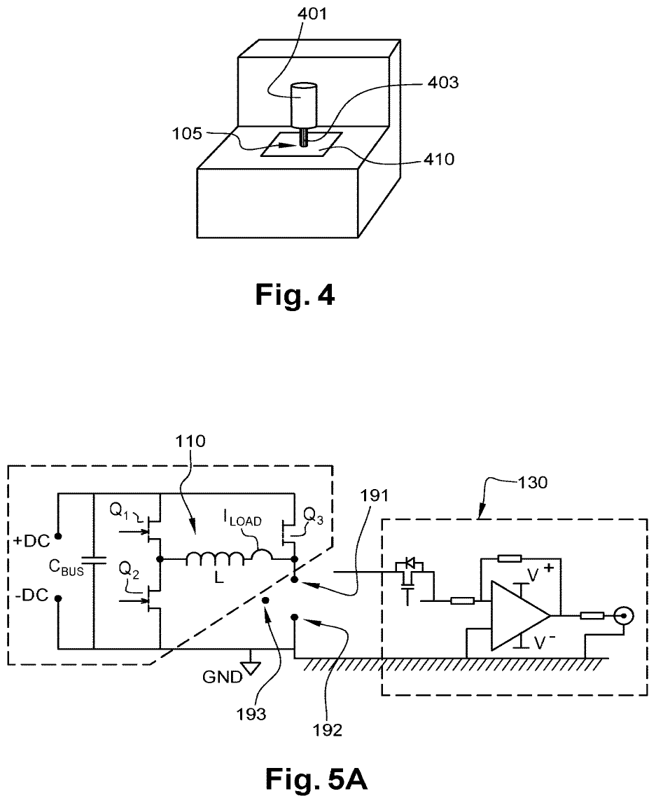

Preferably, a localized heating of the transistor 105 is implemented without significantly heating up the other elements of the measuring circuit, and in particular the switch elements Q1, Q2, Q3. For this purpose, heating may be done by means of an infrared radiation source 401 emitting an infrared beam 403 on the GaN transistor 105, like in the example of arrangement illustrated in FIG. 4. The transistor 105 may be arranged on a receiving support 410, for example in the form of a plate towards which the infrared beam is directed.

The exposure to the IR beam may be intermittent and dependent on the measurement of a temperature sensor, the intermittent control of the beam could be done for example by means of a PID (proportional, integral, derivative) regulator.

It is possible to provide for at least two distinct temperature sensors, a first one which measures the temperature of the transistor 105 and another sensor which measures the environment around. An insulating casing, such as a polyimide-based layer for example of the Kapton™ type may be used to protect the circuit around the transistor 105 when it is subjected to the infrared radiation.

The infrared beam may be an active beam, i.e. whose power can be modulated during exposure. A P.I.D (Proportional, Integral, Derivative) type control circuit could allow regulating the power of this beam. An example of a temperature profile of the transistor 105 includes a temperature rising ramp, then a constant temperature level, and then a falling ramp.

According to one embodiment, the previously-described measuring circuit is integrated on the receiving support 410 and it is the GaN transistor 105 which is affixed and removably arranged on this support 410 while being connected to the measuring circuit. Alternatively, it is possible to provide for a receiving support 410 dedicated to the transistor 105, the rest of the measuring circuit being connected to this support and to the transistor 105, but arranged on another support element.

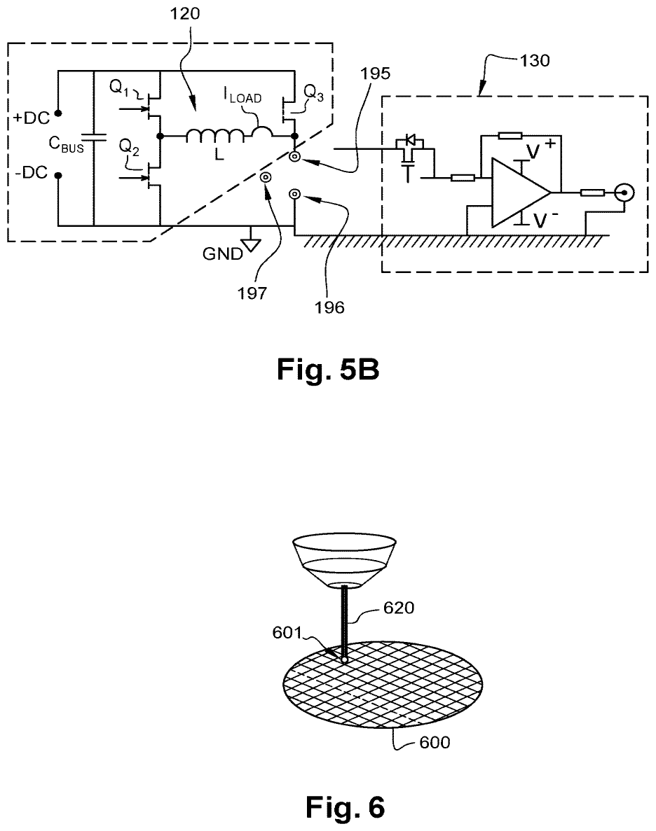

Thus, in the embodiment illustrated in FIG. 5A, the circuit 110 is provided with connection areas 191, 192, 193 (schematically shown in this figure) respectively of the source electrode, of the drain electrode and of the gate electrode of the GaN transistor (not shown). For example, the connection areas 191, 192, 193 may be in the form of conductive pads. When the transistor 105 is located on a wafer (wafer) including other transistors of the same type and which may be distributed over other electronic chips on which the transistor 105 is located, this transistor 105 is temporarily connected to the connection areas 191, 192, 193 and the resistance R_{DS_ONdyn} is assessed. Once the assessment is completed, the transistor 105 is disconnected from the connection areas 191, 192, 193 which are thus cleared and ready to be connected to another transistor to be tested and which could be on the same wafer (wafer) as the transistor 105.

According to another variant, the circuit 110 may be provided with structures 195, 196, 197 for receiving and connecting (schematically shown in FIG. 5B) respectively the source electrode, the drain electrode and the gate electrode of the GaN transistor (not shown). For example, in the case where the transistor 105 is already embedded or mounted on a package, the transistor 105 is arranged on these receiving and connection structures 195, 196, 197 and the resistance R_{DS_ON_dyn} is assessed. Once the assessment is completed, the transistor 105 is removed from the circuit 110 and the structures 195, 196, 197 are thus cleared so as to be able to receive another transistor to be tested, for example another transistor mounted on the package.

The tested GaN-based transistor 105 may be in an integrated form in an SMD (standing for “surface mounted device”) package, or a through package, i.e. provided with connection pins, or a bare chip (i.e. with no package).

In the embodiment illustrated in FIG. 6, the measurement is performed directly on the wafer 600 (“wafer” according to the Anglo-Saxon terminology), even before this wafer is cut, the test circuit (not shown) being connected to the GaN transistor via conductive tips or contact pads.

To measure a package-less bare chip 601, the chip 601 is connected to connection structures (not shown) and this chip 601 is exposed to an infrared beam 620 preferably projected on a face opposite to that one on which the GaN transistor to be tested is arranged.

According to another aspect, the present application aims to protect a method for evaluating the dynamic resistance in the conducting state of a GaN transistor using a device as defined hereinabove, wherein the so-called “measurement” phase is stopped when a criterion of convergence of the current (IL) flowing through the inductive load is met or when a predetermined measurement duration is elapsed.

1. A device for evaluating a dynamic resistance in a conducting state of a GaN-based transistor, comprising a test circuit having:
a first circuit arm, said first circuit arm being provided with a first switch element and with a second switch element connected together at a first node, said test circuit being provided with a third switch element connected to the second node, said third switch element being able to form a second circuit arm of said test circuit with said GaN-based transistor when said GaN-based transistor is connected to the second node,
a power supply delivering a supply voltage to the first circuit arm and to the second circuit arm,
a branch between the first node and the second node provided with an inductive load and with a current sensor, to measure a current flowing through this inductive load,
a measuring switch to alternately connect said GaN-based transistor to a drain-source voltage measuring stage in the conducting state of said GaN-based transistor, and disconnect said GaN-based transistor from said drain-source voltage measuring stage when said measuring switch is set in the non-conducting state,
a control stage of said first, second and third switch elements, of said GaN-based transistor and of the measuring switch, the control stage being configured to:
according to a so-called “measurement” phase, alternately set, once or several times, the test circuit in a first configuration, then in a second configuration, the first configuration being a configuration in which the first switch element and said GaN-based transistor are made conducting whereas the second switch element and the third switch element are made non-conducting, so as to set said power supply in series, said branch, and said GaN-based transistor, the second configuration being a configuration during which the second switch element and the third switch element are in the conducting state whereas the first switch element and said GaN-based transistor are set in the non-conducting state so as to set said branch in closed circuit with said power supply,
the control stage being configured to trigger a connection of the drain-source voltage measuring stage to said GaN-based transistor after the test circuit is set in the first configuration, and to trigger a disconnection of the drain-source voltage measuring stage of said GaN-based transistor before the test circuit is set in the second configuration.

2. The device according to claim 1, wherein the control stage is further configured, prior to the measurement phase, to implement a soaking phase lasting an adjustable predetermined duration, by making the first switch and the third switch conducting whereas the second switch and the GaN-based transistor are kept non-conducting so as to set the first node and the second node at said supply voltage.

3. The device according to claim 1, the control stage being configured to trigger a connection of the drain-source voltage measuring stage to said GaN-based transistor a first non-zero predetermined adjustable delay after the switch circuit is set in the first configuration, and to trigger a disconnection of the drain-source voltage measuring stage from said GaN-based transistor, a second non-zero predetermined adjustable delay before the switch circuit is set in the second configuration.

4. The device according to claim 1, wherein the drain-source voltage measuring stage comprises an operational amplifier mounted as a follower and which non-inverting input are connected to the drain electrode of the first transistor.

5. The device according to claim 1, wherein the control stage is configured to trigger a switch from the first configuration into the second configuration or from the second configuration into the first configuration according to the variation of a signal originating from a circuit for regulating the current of said inductive load, said signal itself originating from said circuit resulting from a comparison between said current flowing through the inductive load and a setpoint value.

6. The device according to claim 5, wherein the regulation circuit is configured to establish the difference between an averaged value of the current flowing through the inductive load and said setpoint, and includes a corrector stage, in particular of the proportional integral type, configured to calculate a duty cycle from this difference, this duty cycle, comprised between zero and one, being representative of a proportion between the duration of said first configuration and the total duration of the successive first configuration and second configuration, the value of the duty cycle being transmitted via said signal originating from a regulation circuit to a pulse-width modulation circuit of the control stage to control the gate of the first switch element, of the second switch element, of the third switch element, and of said GaN-based transistor.

7. The device according to claim 1, further comprising a means for heating the GaN-based transistor, the heating means being in particular provided with an infrared radiation source configured to emit a localized infrared light beam on the GaN-based transistor.

8. The device according to claim 1, wherein said circuit is arranged on a support provided with connection areas or structures on which a source electrode, a drain electrode and a gate electrode of the GaN transistor are respectively connected in a removable manner.

9. The device according to claim 8, wherein the GaN-based transistor is embedded and/or mounted on a package and wherein said circuit is arranged on a support, the connection structures consisting of connection and receiving structures respectively intended to enable a secure assembly of the transistor on said support.

10. The device according to claim 9, wherein the transistor is arranged on a wafer including a plurality of electronic chips, each electronic chip being provided with at least one GaN transistor, the GaN transistor being connected to said support of the switch circuit.

11. A microelectronic method comprising at least one step of evaluating a dynamic resistance in a conducting state of a GaN transistor and based on an assessment device according to claim 10, the method comprising steps of:
connecting the transistor to connection areas in order to assess its drain-source dynamic resistance in the conducting state, then
disconnecting the transistor from said connection areas, then,
cutting the support in order to separate said electronic chips.

12. A method for evaluating the dynamic resistance in the conducting state of a GaN transistor using a device according to claim 1, wherein the so-called “measurement” phase is stopped when a criterion of convergence throughout the inductive load is met or a predetermined measurement duration is elapsed.
